(19) United States
(12) Patent Application Publication
(10) Pub. No.: US 2020/0312733 A1
(43) Pub. Date: Oct. 1, 2020

(54) SEMICONDUCTOR PACKAGE STRUCTURE AND METHOD FOR MANUFACTURING THE SAME

(71) Applicant: Advanced Semiconductor Engineering, Inc., Kaohsiung (TW)

(72) Inventors: Chang-Lin YEH, Kaohsiung (TW); Jen-Chieh KAO, Kaohsiung (TW); Sheng-Yu CHEN, Kaohsiung (TW); Yu-Chang CHEN, Kaohsiung (TW); Yu-Chang CHEN, Kaohsiung (TW)

(73) Assignee: Advanced Semiconductor Engineering, Inc., Kaohsiung (TW)

(21) Appl. No.: 16/370,633

(22) Filed: Mar. 29, 2019

(51) Int. Cl. H01L 23/31; H01L 25/065; H01L 23/00; H01L 23/29; H01L 21/48; H01L 21/56; H01L 25/00

(52) U.S. Cl. CPC H01L 23/3128; H01L 25/0657; H01L 24/16; H01L 23/562; H01L 23/295; H01L 21/4853; H01L 2924/19105; H01L 25/50; H01L 2225/06517; H01L 2225/06558; H01L 2225/06586; H01L 2224/16227; H01L 2924/351; H01L 21/565

(57) ABSTRACT

A semiconductor package structure includes a substrate having a first surface and a second surface opposite to the first surface; a first encapsulant disposed on the first surface of the substrate, and defining a cavity having a sidewall, wherein an accommodating space is defined by the sidewall of the cavity of the first encapsulant and the substrate, and the accommodating space has a volume capacity; and a connecting element disposed adjacent to the first surface of the substrate and in the cavity, wherein a volume of the connecting element is substantially equal to the volume capacity of the accommodating space.

### BACKGROUND

### 1. Field of the Disclosure

The present disclosure relates to a semiconductor package structure and a manufacturing method, and to a semiconductor package structure including an encapsulant and at least one connecting element that extends beyond the encapsulant, and a method for manufacturing the same.

### 2. Description of the Related Art

In general, a semiconductor package may include a substrate with a semiconductor die disposed over the substrate, an interposer, interconnects to form electrical connections between the substrate and the interposer, and a molding compound formed between the substrate and the interposer to encapsulate the semiconductor die and the interconnects. However, a thickness of such a semiconductor package may be greater (e.g., greater than about 1.0 millimeters (mm)) than is specified for some semiconductor packages (e.g., less than about 0.5 mm). Further, bonding the semiconductor package to a motherboard (e.g., a printed circuit board) through pads on a surface of the interposer can be difficult, thus, a quality and yield of a manufacturing process of such a semiconductor package may be low.

### SUMMARY

In some embodiments, a semiconductor package structure includes a substrate having a first surface and a second surface opposite to the first surface; a first encapsulant disposed on the first surface of the substrate, and defining a cavity having a sidewall, wherein an accommodating space is defined by the sidewall of the cavity of the first encapsulant and the substrate, and the accommodating space has a volume capacity; and a connecting element disposed adjacent to the first surface of the substrate and in the cavity, wherein a volume of the connecting element is substantially equal to the volume capacity of the accommodating space.

In some embodiments, a method for manufacturing a semiconductor package structure includes: (a) providing a substrate and a first semiconductor die, wherein the substrate has a first surface and a second surface, and the first semiconductor die is electrically connected to the first surface of the substrate; (b) forming at least one solder bump adjacent to the first surface of the substrate; (c) forming a first encapsulant to encapsulate the first semiconductor die and the solder bump; (d) thinning the first encapsulant and the solder bump to truncate the solder bump and form an outer surface of the first encapsulant, wherein the truncated solder bump is disposed in a cavity defined by the first encapsulant, and a sidewall of the cavity extends from the outer surface of the first encapsulant to the first surface of the substrate; and (e) reflowing the truncated solder bump to form a connecting element, wherein a gap is defined between a periphery surface of the connecting element and a sidewall of the cavity, and the connecting element extends beyond the outer surface of the first encapsulant.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of a semiconductor package structure according to some embodiments of the present disclosure.

FIG. 2 illustrates an enlarged view of area ‘A’ of the semiconductor package structure shown in FIG. 1.

FIG. 3 illustrates an enlarged view of an area of a semiconductor package structure according to some embodiments of the present disclosure.

FIG. 4 illustrates a cross-sectional view of a semiconductor package structure according to some embodiments of the present disclosure.

FIG. 5 illustrates an enlarged view of area 13′ of the semiconductor package structure shown in FIG. 4.

FIG. 6 illustrates a cross-sectional view of a semiconductor package structure according to some embodiments of the present disclosure.

FIG. 7 illustrates a cross-sectional view of a semiconductor package structure according to some embodiments of the present disclosure.

FIG. 8 illustrates one or more stages of an example of a method for manufacturing a semiconductor package structure according to some embodiments of the present disclosure.

FIG. 9 illustrates one or more stages of an example of a method for manufacturing a semiconductor package structure according to some embodiments of the present disclosure.

FIG. 10 illustrates one or more stages of an example of a method for manufacturing a semiconductor package structure according to some embodiments of the present disclosure.

FIG. 11 illustrates one or more stages of an example of a method for manufacturing a semiconductor package structure according to some embodiments of the present disclosure.

FIG. 12 illustrates one or more stages of an example of a method for manufacturing a semiconductor package structure according to some embodiments of the present disclosure.

FIG. 13 illustrates one or more stages of an example of a method for manufacturing a semiconductor package structure according to some embodiments of the present disclosure.

FIG. 14 illustrates one or more stages of an example of a method for manufacturing a semiconductor package structure according to some embodiments of the present disclosure.

FIG. 15 illustrates one or more stages of an example of a method for manufacturing a semiconductor package structure according to some embodiments of the present disclosure.

FIG. 16 illustrates one or more stages of an example of a method for manufacturing a semiconductor package structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the present disclosure are discussed in detail below. It should be appreciated, however, that the present disclosure provides many applicable concepts that can be embodied in a wide variety of specific contexts. The specific embodiments discussed are merely illustrative and do not limit the scope of the present disclosure.

In order to increase package density, for example, a dual-side assembly can be employed for semiconductor package technology. In general, an input/output (I/O) terminal of a package connected to an external board (e.g. a printed circuit board (PCB)) may include an external connector that is exposed from a molding compound of the package. A comparative embodiment of a semiconductor package device may include a substrate, a top semiconductor die, a bottom semiconductor die, a top package body, a bottom package body and at least one first solder bump. The top semiconductor die is electrically connected to a top surface of the substrate. The top package body covers the top semiconductor die. The bottom semiconductor die and the first solder bump are electrically connected to a bottom surface of the substrate. The bottom package body covers the bottom semiconductor die and the first solder bump. A laser ablation may be used to form a hole on the bottom package body to expose a portion of the first solder bump. A second solder bump or a complement solder paste is added to the exposed first solder bump, and those components are fused together to form an external connector extending beyond the bottom package body. The manufacturing cost of such semiconductor package device may be relatively high. Further, a thickness of such a semiconductor package device is greater (e.g., greater than about 1.0 mm) than is specified for some semiconductor packages (e.g., less than about 0.75 mm or about 0.5 mm). In addition, since a maximum diameter of the first solder bump may be relatively small, such as about 200 micrometers (μm) or less or about 230 μm or less, the maximum diameter of the external connector is relatively small. As used herein, the term “maximum diameter” may refer to a maximum distance between any two edges or outer portions of a component (which may, but need not, be substantially spherical or substantially ball shaped). Thus, after such a semiconductor package device is connected to the external board (e.g. PCB board), the stress of the external connector is relatively high, and the drop test performance is poor. As a result, the yield of the bonding between the semiconductor package device and the external board is reduced.

At least some embodiments of the present disclosure provide for a semiconductor package structure which may omit a complement solder paste or solder bump. At least some embodiments of the present disclosure further provide for techniques for manufacturing the semiconductor package structure.

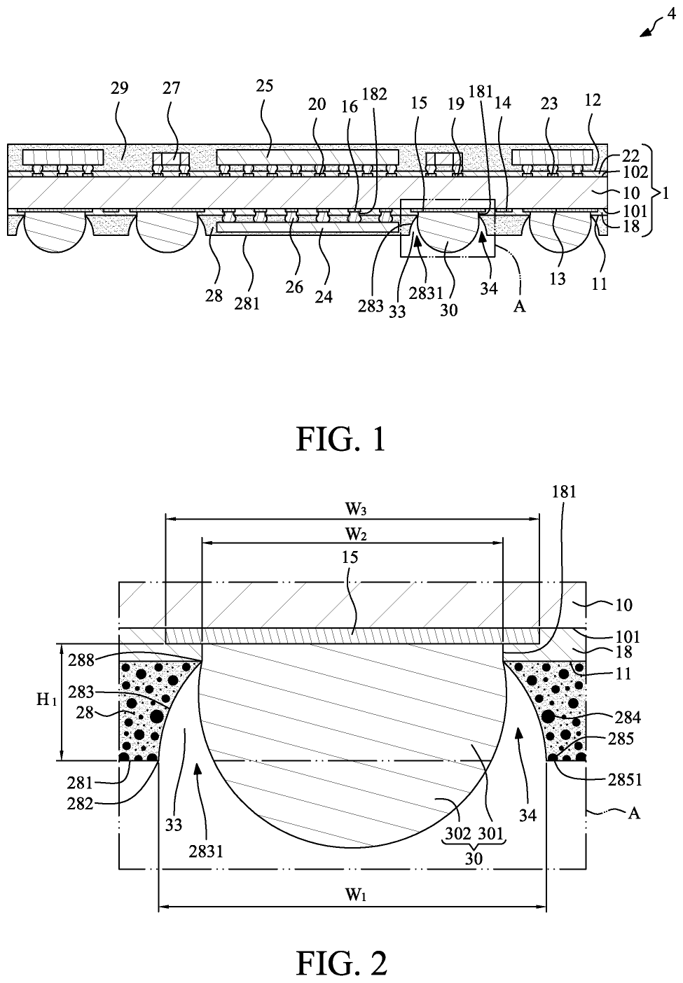

FIG. 1 illustrates a cross-sectional view of a semiconductor package structure 4 according to some embodiments of the present disclosure. The semiconductor package structure 4 includes a substrate 1, a first semiconductor die 24, a second semiconductor die 25, a first encapsulant 28, a second encapsulant 29 and at least one connecting element 30.

The substrate 1 is a package substrate, and has a first surface 11 and a second surface 12 opposite to the first surface 11. The substrate 1 includes a substrate body 10, a first circuit layer 13, a first insulation layer 18, a second circuit layer 19 and a second insulation layer 22. The substrate body 10 has a first surface 101 and a second surface 102 opposite to the first surface 101. The first circuit layer 13 is disposed adjacent to or disposed on the first surface 101 of the substrate body 10, and includes one or more conductive traces 14, one or more first outer pads 15 (e.g., bump pads) and one or more first inner pads 16 (e.g., bump pads). As shown in FIG. 1, the first circuit layer 13 may be the bottom or bottommost circuit layer of the substrate 1.

The conductive traces 14 may be disposed between first outer pads 15. For example, as illustrated in FIG. 1, one conductive trace 14 is arranged between two adjacent first outer pads 15. In some embodiments, two or more conductive traces 14, or no conductive traces 14, may be arranged between two adjacent first outer pads 15. The first insulation layer 18 (which may include, for example, a solder mask) covers the first surface 101 of the substrate body 10 and one or more portions of the first circuit layer 13. The first insulation layer 18 defines at least one first outer through hole 181 to expose one of the first outer pads 15 and at least one first inner through hole 182 to expose one of the first inner pads 16.

The first semiconductor die 24 is electrically connected to the first surface 11 of the substrate 1. In some embodiments, the first semiconductor die 24 is disposed adjacent to the first surface 101 of the substrate body 10, and is electrically connected to the first inner pads 16 of the first circuit layer 13 on the first surface 101 of the substrate body 10. In some embodiments, the first semiconductor die 24 is electrically connected to the first circuit layer 13 by flip chip bonding, and the first semiconductor die 24 is connected to the first inner pads 16 through a plurality of first conductive bumps 26. In some embodiments, the first semiconductor die 24 may be electrically connected to the first circuit layer 13 by wire bonding.

The first encapsulant 28 is disposed adjacent to or disposed on the first surface 11 of the substrate 1, covers the first insulation layer 18, and encapsulates the first semiconductor die 24. The material of the first encapsulant 28 may include a molding compound. The first encapsulant 28 has an outer surface 281 (e.g., a bottom surface or an outermost surface), and defines a cavity 283 around a periphery of the first semiconductor die 24. The cavity 283 of the first encapsulant 28 and the substrate 1 collectively define an accommodating space 34 having a volume capacity. In some embodiments, the cavity 283 of the first encapsulant 28 corresponds to the first outer through hole 181 to expose a portion (e.g., the first outer pad 15) of the first circuit layer 13. Thus, the accommodating space 34 further includes a space defined by the first outer through hole 181. The volume capacity of the accommodating space 34 may be the sum of a volume capacity of the cavity 283 of the first encapsulant 28 and a volume capacity of the first outer through hole 181 of the first insulation layer 18.

The connecting element 30 is disposed adjacent to the first surface 11 of the substrate 1, and is disposed in the cavity 283. In the embodiment of FIG. 1, the semiconductor package structure 4 includes a plurality of connecting elements 30 that are disposed over respective ones of the first outer pads 15 positioned around the first semiconductor die 24. In the embodiment of FIG. 1, the connecting element 30 is formed by reflowing a truncated solder bump (e.g., rather than by fusing two stacked solder bumps or fusing a solder bump and a complement solder paste). Thus, the periphery surface of the connecting element 30 may be a curved surface due to cohesion forces. In some embodiments, a portion of the connecting element 30 is substantially spherical, and the peripheral surface of the connecting element 30 has one center of curvature. In some embodiments, the connecting element 30 may have a shape that is a portion of an object having a sphericity (specified as a ratio of a surface area of a sphere (with a same volume as the object) to a surface area of the object) of about 0.9 or greater, such as about 0.93 or greater, or about 0.95 or greater, or about 0.98 or greater, and may not include any neck portion (e.g., a portion having substantially straight sides, such as a cylindrical portion). The connecting element 30 may include a first portion 301 and a second portion 302 (see FIG. 2). The first portion 301 of the connecting element 30 is within the first encapsulant 28 (e.g. does not protrude from the encapsulant 28), and the second portion 302 of the connecting element 30 protrudes from the outer surface 281 of the first encapsulant 28, beyond the cavity 283. The second portion 302 may also be referred to as an end portion of the connecting element 30. The connecting element 30 is disposed adjacent to the first surface 101 of the substrate body 10, and may not be encapsulated or covered by the first encapsulant 28. In the embodiments of FIG. 1, a volume of the connecting element 30 is substantially equal to the volume capacity of the accommodating space 34. In addition, the second portion 302 of the connecting element 30 is a free end (not bonded or connected to another device or component) in the semiconductor package structure 4. In further manufacturing or assembly processes, the free end may be bonded or connected to another device or component.

A gap 33 is defined between a periphery surface of the first portion 301 of the connecting element 30 and a sidewall of a portion of the cavity 283. A maximum lateral width W₁ of the cavity 283 (e.g., a maximum width W₁ of an opening 2831 in the surface 281) is greater than a maximum lateral width of the connecting element 30, thus, there is a space (the gap 33) between the periphery of the first portion 301 of the connecting element 30 and the sidewall of the portion of the cavity 283, and the connecting element 30 does not fully fill the cavity 283. In addition, the second portion 302 of the connecting element 30 extends beyond/protrudes from an outer surface 281 of the first encapsulant 28, where the outer surface 281 of the first encapsulant 28 is a bottom surface of the first encapsulant 28 on the side of the semiconductor package structure 4 including the first encapsulant 28, and is substantially parallel with the first surface 11 of the substrate 1.

The second circuit layer 23 is disposed adjacent to or disposed on the second surface 102 of the substrate body 10, and includes one or more second outer pads 19 and one or more second inner pads 20. As shown in FIG. 1, the second circuit layer 23 may be the top or topmost circuit layer of the substrate 1. The second insulation layer 22 (e.g., a solder mask) covers the second surface 102 of the substrate body 10 and portions of the second circuit layer 23. The second insulation layer 22 defines a plurality of second through holes to expose a portion (e.g., the second outer pads 19 and the second inner pads 20) of the second circuit layer 23.

The second semiconductor die 25 is electrically connected to the second surface 12 of the substrate 1. In some embodiments, the second semiconductor die 25 is disposed adjacent to the second surface 102 of the substrate body 10, and is electrically connected to the second inner pads 20 of the second circuit layer 23 on the second surface 102 of the substrate body 10. In some embodiments, the second semiconductor die 25 is electrically connected to the second circuit layer 23 by flip chip bonding, and the second semiconductor die 25 is connected to the second inner pads 20 through a plurality of conductive bumps. In some embodiments, the second semiconductor die 25 may be electrically connected to the second circuit layer 23 by wire bonding. In some embodiments, the semiconductor package structure 4 may further include at least one passive component 27 disposed adjacent to the second surface 102 of the substrate body 10, and electrically connected to the second outer pads 19 of the second circuit layer 23.

The second encapsulant 29 is disposed adjacent to or disposed on the second surface 12 of the substrate 1, covers the second insulation layer 22, and encapsulates the second semiconductor die 25 and the passive component 27. The material of the second encapsulant 29 may include a molding compound.

FIG. 2 illustrates an enlarged view of area ‘A’ of the semiconductor package structure 4 shown in FIG. 1. The gap 33 extends to the first surface 11 of the substrate 1, and in some embodiments the connecting element 30 does not contact the first encapsulant 18 from a cross-sectional view. Alternatively, or in conjunction, a tip point (e.g., only a tip point) of the first encapsulant 28 contacts the connecting element 30, and the connecting element 30 does not contact the sidewall of the cavity 283 from a cross-sectional view. The tip point of the first encapsulant 28 may be a portion of the encapsulant 28 adjacent to or contacting the first insulation layer 18. As shown in FIG. 2, the sidewall of the cavity 283 extends from an outer surface 281 of the first encapsulant 28 to the first surface 11 of the substrate 1. The sidewall of the cavity 283 extends from a bottom corner 282 of the first encapsulant 28 to a top corner 288 of the first encapsulant 28. The top corner 288 of the first encapsulant 28 may contact the first encapsulant 18. For example, the top corner 288 of the first encapsulant 28 may be at a bottom corner of the first encapsulant 18. Thus, the cavity 283 extends through the first encapsulant 28, and exposes a portion (e.g., the first outer through hole 181 and the first outer pad 15) of the substrate 1. The sidewall of the cavity 283 (e.g., of the entire sidewall of the cavity 283) is a continuous surface. A curvature of the sidewall of the cavity 283 (e.g., of the entire sidewall of the cavity 283) may be continuous. There may be no turning point at an apex or peak on the sidewall of the cavity 283. For example, a portion of the sidewall of the cavity 283 may define a portion of a substantially spherical shape. Alternatively, or in conjunction, the sidewall of the cavity 283 may have a shape that is a portion of an object having a sphericity of about 0.9 or greater, such as about 0.93 or greater, or about 0.95 or greater, or about 0.98 or greater, and the shape of the sidewall of the cavity 283 may be a portion of a circle from a cross-sectional view. The sidewall of the cavity 283 may have one center of curvature.

In addition, the first encapsulant 28 includes a plurality of first fillers 284 adjacent to the sidewall of the cavity 283 and a plurality of second fillers 285 adjacent to the outer surface 281 of the first encapsulant 28. Since the cavity 283 may be formed around a truncated solder bump (e.g., rather than by laser drilling), the first fillers 284 near or nearest the sidewall of the cavity 283 may be completely or substantially intact and uncut. The first fillers 284 maintain their original substantially spherical shapes and have no machining mark. Further, a surface roughness of the sidewall of the cavity 283 (e.g., of the entire sidewall of the cavity 283) is substantially consistent. In addition, the outer surface 281 of the first encapsulant 28 may be formed by machining such as grinding, thus, some of the second fillers 285 are truncated and exposed on the outer surface 281 of the first encapsulant 28. Each of the truncated second fillers 285 has a substantially flat surface 2851, and the surfaces 2851 of the truncated second fillers 285 may be substantially coplanar with the outer surface 281 of the first encapsulant 28. In addition, a surface roughness of the sidewall of the cavity 283 is less than a surface roughness of the outer surface 281 of the first encapsulant 28 (e.g., by a factor of about 0.9 or less, or by a factor of about 0.8 or less, or by a factor of about 0.7 or less).

A height H₁ is measured from a bottom surface of the first outer pad 15 to the outer surface 281 of the first encapsulant 28 along a vertical direction of the substrate 1 in the orientation shown in FIG. 2. The cavity 283 of the first encapsulant 28 defines an opening 2831 on the outer surface 281 of the first encapsulant 28. The opening 2831 has a maximum width W₁. Further, the first outer through hole 181 has a maximum width W₂, and the first outer pad 15 has a maximum width W₃. A ratio of the maximum width W₁ of the opening 2831 of the cavity 283 to the maximum width W₂ of the first outer through hole 181 is equal to or greater than about 1.08, such as greater than about 1.10, about 1.16, about 1.18, about 1.19, about 1.21, about 1.26, about 1.28, about 1.29, or about 1.30. The maximum width W₁ of the opening 2831 of the cavity 283 may be greater than the maximum width W₃ of the first outer pad 15 (e.g., by a factor of about 1.10 or more, about 1.16 or more, about 1.18 or more, about 1.19 or more, about 1.21 or more, about 1.26 or more, about 1.28 or more, about 1.29 or more, or about 1.30 or more). In one embodiment analyzed by simulation, the connecting element 30 is formed from a solder component 40 (see FIG. 8) having a maximum diameter of 290 μm, the maximum width W₂ of the first outer through hole 181 is 230 μm, a pitch between two first outer pads 15 is 0.4 mm, and various simulation results are illustrated as follows.

For H₁=13 μm, then, W₁=249.0 μm, thus, the ratio of W₁ to W₂ is 1.08.

For H₁=40 μm, then, W₁=277.8 μm, thus, the ratio of W₁ to W₂ is 1.21.

For H₁=60 μm, then, W₁=290.7 μm, thus, the ratio of W₁ to W₂ is 1.26.

For H₁=80 μm, then, W₁=297.5 μm, thus, the ratio of W₁ to W₂ is 1.29.

For H₁=100 μm, then, W₁=298.9 μm, thus, the ratio of W₁ to W₂ is 1.30.

For H₁=120 μm, then, W₁=295.1 μm, thus, the ratio of W₁ to W₂ is 1.28.

For H₁=180 μm, then, W₁=247.4 μm, thus, the ratio of W₁ to W₂ is 1.08.

In one embodiment analyzed by simulation, the connecting element 30 is formed from a solder component 40 (FIG. 8) having a maximum diameter of 290 μm, the maximum width W₂ of the first outer through hole 181 is 250 μm, a pitch between two first outer pads 15 is 0.4 mm, and various simulation results are illustrated as follows.

For H₁=15 μm, then, W₁=267.8 μm, thus, the ratio of W₁ to W₂ is 1.07.

For H₁=40 μm, then, W₁=289.3 μm, thus, the ratio of W₁ to W₂ is 1.16.

For H₁=60 μm, then, W₁=298.5 μm, thus, the ratio of W₁ to W₂ is 1.19.

For H₁=80 μm, then, W₁=302.8 μm, thus, the ratio of W₁ to W₂ is 1.21.

For H₁=100 μm, then, W₁=301.4 μm, thus, the ratio of W₁ to W₂ is 1.21.

For H₁=120 μm, then, W₁=295.0 μm, thus, the ratio of W₁ to W₂ is 1.18.

For H₁=155 μm, then, W₁=269.6 μm, thus, the ratio of W₁ to W₂ is 1.08.

The above simulation results show that for ratios of W₁ to W₂ is equal to or greater than 1.08, the value of W₁ is smallest when the ratio of W₁ to W₂ is equal to 1.08. In the embodiments illustrated in FIG. 1 and FIG. 2, the maximum width W₁ of the opening 2831 of the cavity 283 is greater than the maximum width W₂ of the first outer through hole 181 by a ratio equal to or greater than about 1.08 (e.g., greater than about 1.10, about 1.16, about 1.18, about 1.19, about 1.21, about 1.26, about 1.28, about 1.29, or about 1.30), thus, the maximum width W₁ of the opening 2831 of the cavity 283 is relatively large. As shown in FIG. 6, when the connecting element 30 is bonded to a device 36 (e.g., a motherboard or a semiconductor package) to serve as a bonding structure 31, the stress of the bonding structure 31 is relatively small since a lateral area of the bonding structure 31 (e.g., the area of the opening 2831 of the cavity 283) is relatively large. Thus, the drop test performance of the semiconductor package structure 5 (FIG. 6) is relatively good and is improved relative to certain comparative package structures. In addition, as shown in FIG. 2, at the bottom corner 282 of the first encapsulant 28, an inclination angle between the outer surface 281 of the first encapsulant 28 and the sidewall of the cavity 283 is greater than about 90 degrees, thus, a stress concentration effect can be avoided, which increases the reliability of bonding.

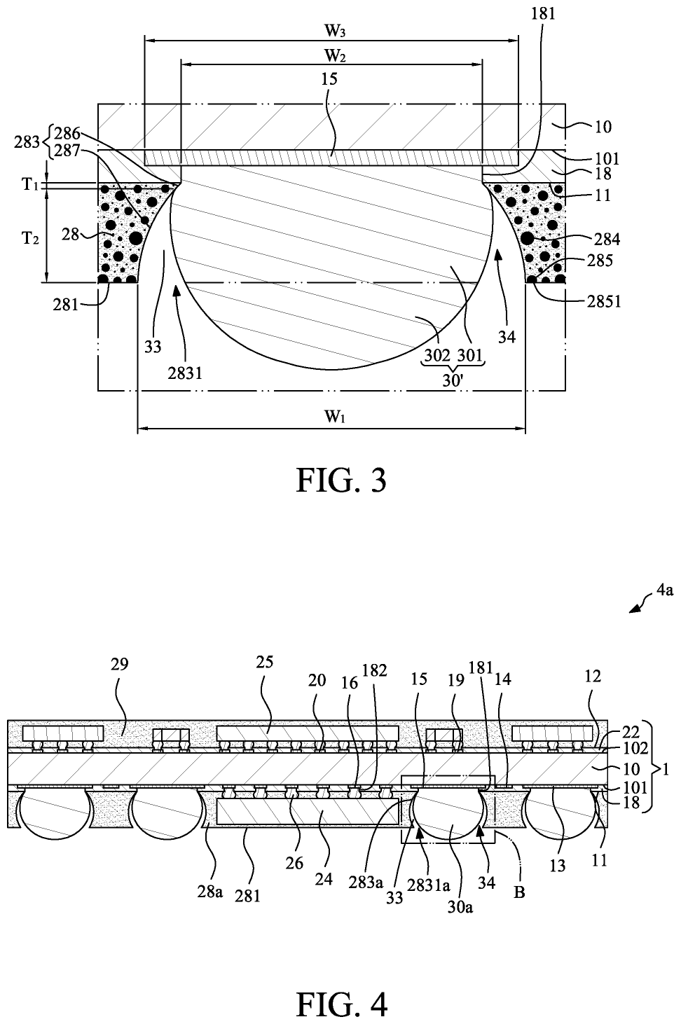

FIG. 3 illustrates an enlarged view of an area of a semiconductor package structure according to some embodiments of the present disclosure. The embodiment of FIG. 3 is similar to the embodiment illustrated in FIG. 2, except for the structure of the connecting element 30′. As shown in FIG. 3, the first encapsulant 28 includes a first portion 286 and a second portion 287. The first portion 286 is in contact with the connecting element 30′, and has a thickness T₁. The second portion 287 is spaced apart from the connecting element 30′, and has a thickness T₂. The thickness T₁ of the first portion 286 may be less than about one fifth of a thickness T₂ of the second portion 286. The thickness T₁ of the first portion 286 may be less than about one tenth of a thickness T₂ of the second portion 286. The connecting element 30′ may contact a portion of the sidewall of the cavity 283.

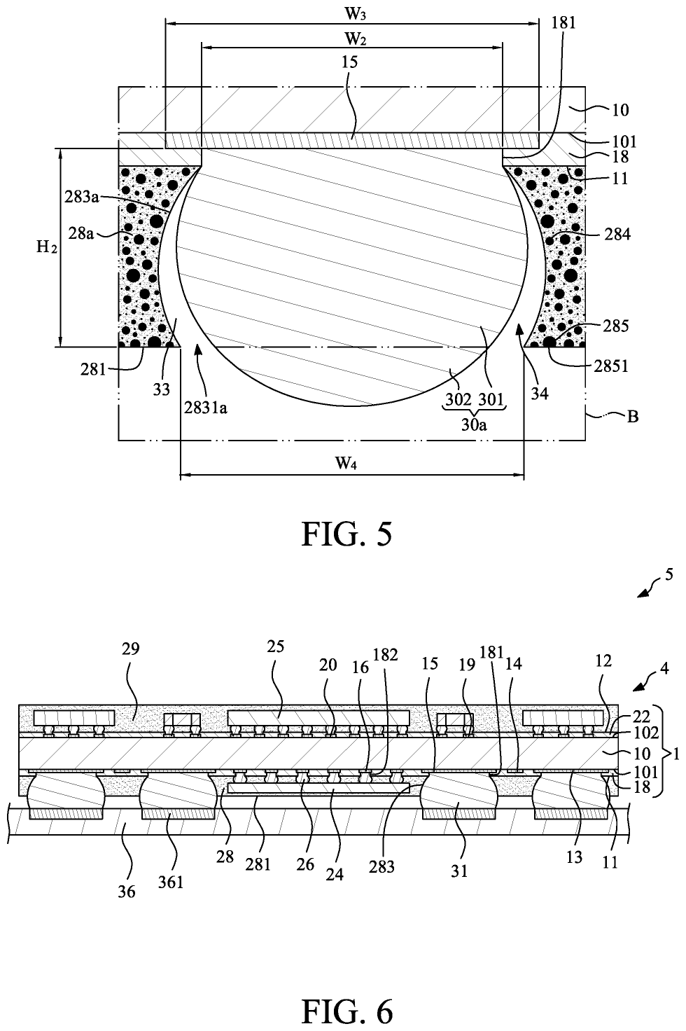

FIG. 4 illustrates a cross-sectional view of a semiconductor package structure 4a according to some embodiments of the present disclosure. FIG. 5 illustrates an enlarged view of area ‘B’ of the semiconductor package structure 4a shown in FIG. 4. The semiconductor package structure 4a of FIG. 4 is similar to the semiconductor package structure 4 illustrated in FIG. 1, except for the structures of the first encapsulant 28a and the connecting element 30a. The thickness of the first encapsulant 28a of FIG. 4 is greater than the thickness of the first encapsulant 28 of FIG. 1 (e.g., by a factor of about 1.1 or more, by a factor of about 1.2 or more, or by a factor of about 1.3 or more). Thus, the height H₂ of FIG. 5 is greater than the height H₁ of FIG. 2. Further, the curvature of the sidewall of the cavity 283 of FIG. 4 and FIG. 5 may be different from the curvature of the sidewall of the cavity 283 of FIG. 1 and FIG. 2. For example, the sidewall of the cavity 283 of FIG. 1 and FIG. 2 may have a distance from the connecting element 30 that increases (e.g. monotonically) going from a top portion of the sidewall of the cavity 283 to a bottom portion of the sidewall of the cavity 283. The sidewall of the cavity 283 of FIG. 4 and FIG. 5 may have a distance from the connecting element 30a that increases (e.g. monotonically) going from a top portion of the sidewall of the cavity 283 to a middle portion of the sidewall of the cavity 283 (which need not be or include an exact center of the sidewall of the cavity 283), and that decreases (e.g. monotonically) going from the middle portion of the sidewall of the cavity 283 to a bottom portion of the sidewall of the cavity 283.

The maximum width W₄ of the opening 2831a of the cavity 283 of FIG. 4 and FIG. 5 may be less than the maximum width W₁ of the opening 2831 of the cavity 283 of FIG. 1 and FIG. 2 (e.g., by a factor of about 0.9 or less, or by a factor of about 0.8 or less, or by a factor of about 0.7 or less). The maximum width W₄ of the opening 2831a of the cavity 283 may be equal to or less than the maximum width W₂ of the first outer through hole 181 (e.g., by a factor of about 0.9 or less, or by a factor of about 0.8 or less, or by a factor of about 0.7 or less). The maximum width W₄ of the opening 2831a of the cavity 283 may be equal to or less than the maximum width W₃ of the first outer pad 15 (e.g., by a factor of about 0.9 or less, or by a factor of about 0.8 or less, or by a factor of about 0.7 or less). In addition, the volume of the connecting element 30a of FIG. 4 and FIG. 5 is greater than the volume of the connecting element 30 of FIG. 1 and FIG. 2 (e.g., by a factor of about 1.1 or more, by a factor of about 1.2 or more, or by a factor of about 1.3 or more).

FIG. 6 illustrates a cross-sectional view of a semiconductor package structure 5 according to some embodiments of the present disclosure. The semiconductor package structure 5 of FIG. 6 is similar to the semiconductor package structure 4 illustrated in FIG. 1 and FIG. 2, except that the semiconductor package structure 5 further includes a device 36 that may include or may be a motherboard or a semiconductor package. The device 36 is spaced apart from the substrate 1, and includes at least one electrical contact 361 (e.g., a bonding pad) adjacent to a surface thereof. As shown in FIG. 6, the connecting element 30 of the semiconductor package structure 4 is bonded to the device 36. In one embodiment, the connecting element 30 is fused with a complement material (such as a pre-solder or paste) on the electrical contact 361 to become a bonding structure 31. The bonding structure 31 substantially fills the cavity 283 and contacts the electrical contact 361. As stated above, the stress of the bonding structure 31 is relatively small since a lateral area of the bonding structure 31 (e.g., the area of an opening 2831 of a cavity 283) is relatively large. Thus, the drop test performance of the semiconductor package structure 5 (FIG. 6) is relatively good. In addition, the bonding structure 31 may have no turning point at an apex or peak, thus, a stress concentration effect can be avoided, which increases the reliability of bonding.

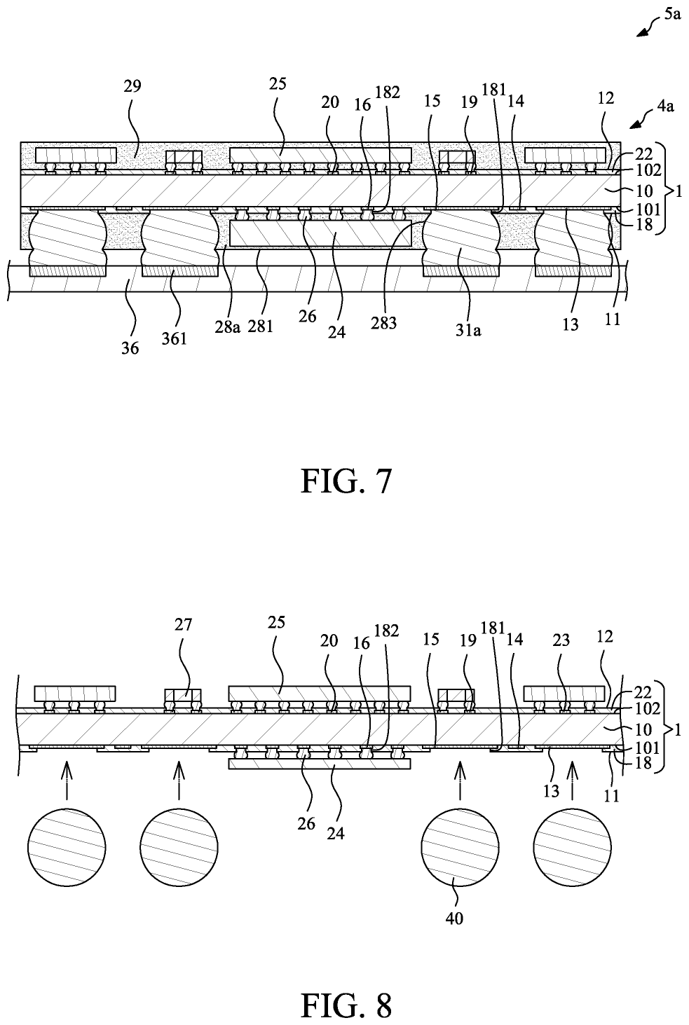

FIG. 7 illustrates a cross-sectional view of a semiconductor package structure 5a according to some embodiments of the present disclosure. The semiconductor package structure 5a of FIG. 7 is similar to the semiconductor package structure 5 illustrated in FIG. 6, except that the semiconductor package structure 4a replaces the semiconductor package structure 4 of FIG. 6. The semiconductor package structure 4a of FIG. 7 is the same as or is similar to the semiconductor package structure 4a of FIG. 4. As shown in FIG. 7, the bonding structure 31a is in a shape of a calabash or has a rounded hourglass shape.

FIGS. 8 to 14 illustrate a method for manufacturing a semiconductor package structure according to some embodiments of the present disclosure. In some embodiments, the method is for manufacturing the semiconductor package structure 1 shown in FIG. 1 and FIG. 2. Referring to FIG. 8, a substrate 1, a first semiconductor die 24, a second semiconductor die 25 and at least one passive component 27 are provided. The substrate 1 is a package substrate, and has a first surface 11 and a second surface 12 opposite to the first surface 11. The substrate 1 includes a substrate body 10, a first circuit layer 13, a first insulation layer 18, a second circuit layer 19 and a second insulation layer 22. The substrate body 10 has a first surface 101 and a second surface 102 opposite to the first surface 101. The first circuit layer 13 is disposed adjacent to or disposed on the first surface 101 of the substrate body 10, and includes one or more conductive traces 14, one or more first outer pads 15 (e.g., bump pads) and one or more first inner pads 16 (e.g., bump pads). As shown in FIG. 8, the first circuit layer 13 may be a bottom or bottommost circuit layer of the substrate 1. The conductive traces 14 may be disposed between first outer pads 15. For example, as illustrated in FIG. 8, one conductive trace 14 is routed between two adjacent first outer pads 15. In some embodiments, two or more conductive traces 14, or no conductive traces 14, may be routed between two adjacent first outer pads 15. The first insulation layer 18 (e.g., that includes a solder mask) covers the first surface 101 of the substrate body 10 and portions of the first circuit layer 13. The first insulation layer 18 defines at least one first outer through hole 181 to expose respective one of the first outer pads 15 and at least one first inner through hole 182 to expose respective one of the first inner pads 16.

The first semiconductor die 24 is electrically connected to the first surface 11 of the substrate 1. In some embodiments, the first semiconductor die 24 is disposed adjacent to the first surface 101 of the substrate body 10, and is electrically connected to the first inner pads 16 of the first circuit layer 13 on the first surface 101 of the substrate body 10. In some embodiments, the first semiconductor die 24 is electrically connected to the first circuit layer 13 by flip chip bonding, and the first semiconductor die 24 is connected to the first inner pads 16 through a plurality of first conductive bumps 26. In some embodiments, the first semiconductor die 24 may be electrically connected to the first circuit layer 13 by wire bonding.

The second circuit layer 23 is disposed adjacent to or disposed on the second surface 102 of the substrate body 10, and includes one or more second outer pads 19 and one or more second inner pads 20. As shown in FIG. 8, the second circuit layer 23 may be a top or topmost circuit layer of the substrate 1. The second insulation layer 22 (e.g., that includes a solder mask) covers the second surface 102 of the substrate body 10 and portions of the second circuit layer 23. The second insulation layer 22 defines a plurality of second through holes to expose a portion (e.g., the second outer pads 19 and the second inner pads 20) of the second circuit layer 23.

The second semiconductor die 25 is electrically connected to the second surface 12 of the substrate 1. In some embodiments, the second semiconductor die 25 is disposed adjacent to the second surface 102 of the substrate body 10, and is electrically connected to the second inner pads 20 of the second circuit layer 23 on the second surface 102 of the substrate body 10. In some embodiments, the second semiconductor die 25 is electrically connected to the second circuit layer 23 by flip chip bonding, and the second semiconductor die 25 is connected to the second inner pads 20 through a plurality of conductive bumps. In some embodiments, the second semiconductor die 25 may be electrically connected to the second circuit layer 23 by wire bonding. The passive component 27 is disposed adjacent to the second surface 102 of the substrate body 10, and is electrically connected to the second outer pads 19 of the second circuit layer 23.

One or more solder components 40 are provided. Each of the solder components 40 has a maximum diameter equal to or greater than about 280 μm, such as about 290 μm, about 300 μm or about 320 μm. The maximum diameter of the solder components 40 may be equal to or greater than the maximum width W₃ of the first outer pad 15 and/or the maximum width W₂ of the first outer through hole 181 (see FIG. 10), such as by a factor of about 1.1 or more, about 1.2 or more, or about 1.3 or more. The solder components 40 include tin (Sn) solder, lead-tin (PbSn) based solder or tin-silver (SnAg) based solder.

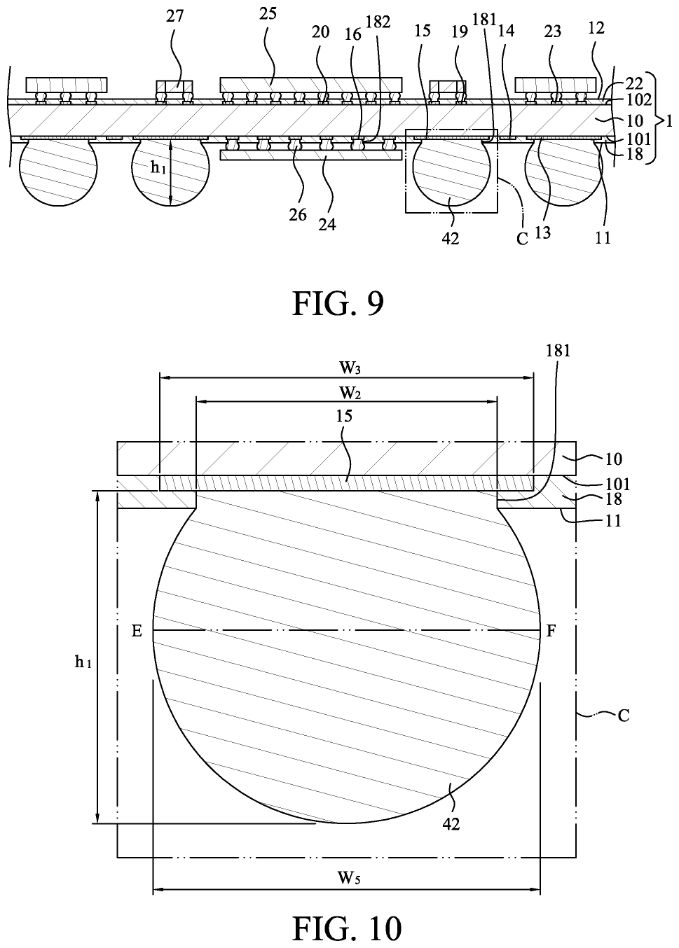

Referring to FIG. 9, the solder components 40 are disposed over respective ones of the first outer pads 15 to form at least one solder bump 42 adjacent to the first surface 11 of the substrate 1. Thus, the solder bump 42 is disposed on the first outer pads 15 of the first circuit layer 13 of the substrate 1.

FIG. 10 illustrates an enlarged view of area ‘C’ shown in FIG. 9. A first height h₁ is measured from a bottom surface of the first outer pad 15 to a bottom end of the solder bump 42 along a vertical direction of the substrate 1 in the orientation shown in FIG. 10. Thus, the solder bump 42 has the first height h₁. As shown in FIG. 10, a distance from point E to point F is a maximum width W₅ of the solder bump 42. The solder bump 42 has a maximum lateral area on a plane including point E and point F, and the plane is parallel with the first surface 11 of the substrate 1. The maximum width W₅ of the solder bump 42 is greater than the maximum width W₂ of the first outer through hole 181 (e.g. by a factor of about 1.1 or more, about 1.2 or more, or about 1.3 or more), and the maximum width W₅ of the solder bump 42 is greater than the maximum width W₃ of the first outer pad 15 (e.g. by a factor of about 1.1 or more, about 1.2 or more, or about 1.3 or more).

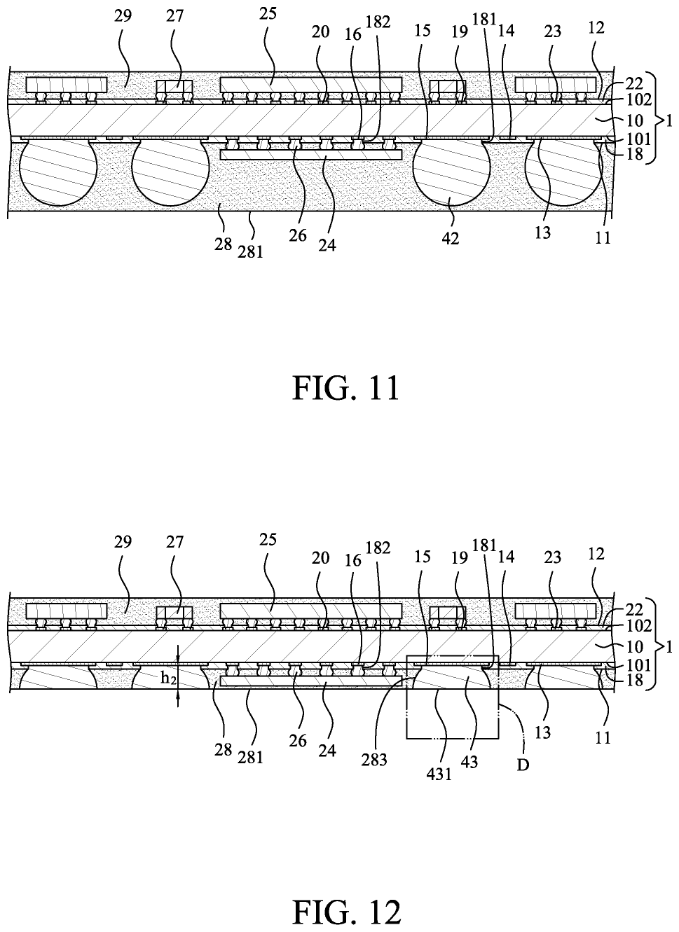

Referring to FIG. 11, the first encapsulant 28 and the second encapsulant 29 may be formed (e.g., may be formed concurrently). The second encapsulant 29 is disposed adjacent to or disposed on the second surface 12 of the substrate 1, covers the second insulation layer 22, and encapsulates the second semiconductor die 25 and the passive component 27. The material of the second encapsulant 29 may include a molding compound. In addition, the first encapsulant 28 is disposed adjacent to or disposed on the first surface 11 of the substrate 1, covers the first insulation layer 18, and encapsulates the first semiconductor die 24 and the solder bump 42. The material of the first encapsulant 28 may include a molding compound. The first encapsulant 28 has an outer surface 281 (e.g., a bottom surface). In some embodiments, the second encapsulant 29 may be disposed adjacent to or disposed on the second surface 12 of the substrate 1 at the stage of FIG. 8 to cover the second insulation layer 22 and encapsulate the second semiconductor die 25 and the passive component 27.

Referring to FIG. 12, a portion of the first encapsulant 28 and the solder bump 42 are removed (e.g., concurrently) by, for example, grinding. Thus, the first encapsulant 28 and the solder bump 42 are thinned (e.g., concurrently) so that the first encapsulant 28 has an outer surface 281, the solder bump 42 is truncated to become a truncated solder bump 43 having a substantially flat surface 431. The surface 431 of the truncated solder bump 43 may be substantially coplanar with the outer surface 281 of the first encapsulant 28. The truncated solder bump 43 is disposed in a cavity 283 defined by the first encapsulant 28. In one embodiment, a shape and a size of the cavity 283 are determined by the truncated solder bump 43 and/or the first encapsulant 28.

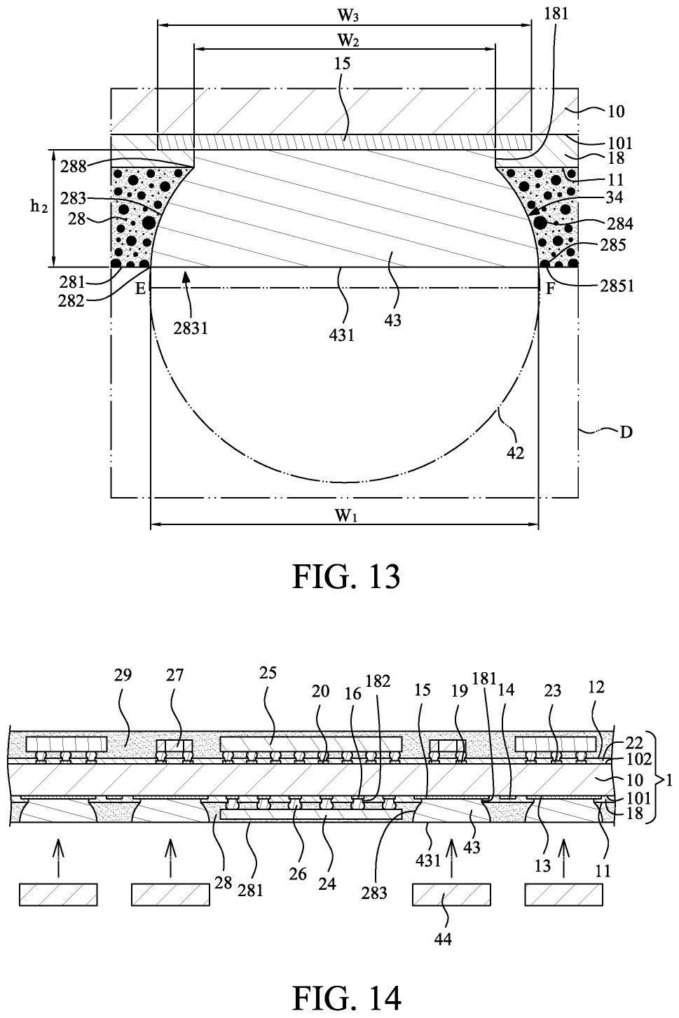

FIG. 13 illustrates an enlarged view of area ‘D’ shown in FIG. 12. The cavity 283 of the first encapsulant 28 and the substrate 1 collectively define an accommodating space 34 having a volume capacity. In some embodiments, the cavity 283 of the first encapsulant 28 corresponds to the first outer through hole 181 to expose a portion (e.g., the first outer pad 15) of the first circuit layer 13. Thus, the accommodating space 34 includes a space defined by the first outer through hole 181. The volume capacity of the accommodating space 34 may be approximately the sum of a volume capacity of the cavity 283 of the first encapsulant 28 and a volume capacity of the first outer through hole 181 of the first insulation layer 18.

As shown in FIG. 13, the sidewall of the cavity 283 extends from an outer surface 281 of the first encapsulant 28 to the first surface 11 of the substrate 1. The sidewall of the cavity 283 extends from a bottom corner 282 of the first encapsulant 28 to a top corner 288 of the first encapsulant 28. The top corner 288 of the first encapsulant 28 may contact the first encapsulant 18. For example, the top corner 288 of the first encapsulant 28 may be disposed at a bottom corner of the first encapsulant 18. Thus, the cavity 283 extends through the first encapsulant 28, and exposes a portion (e.g., the first outer through hole 181 and the first outer pad 15) of the substrate 1. The sidewall of the cavity 283 (e.g., of the entire sidewall of the cavity 283) is a continuous surface. A curvature of the sidewall of the cavity 283 (e.g., of the entire sidewall of the cavity 283) is continuous. There is no turning point at an apex or peak on the sidewall of the cavity 283 (e.g., of the entire sidewall of the cavity 283). For example, a portion of the sidewall of the cavity 283 may be substantially spherical. The sidewall of the cavity 283 may have a shape that is a portion of a substantially spherical shape, and the sidewall of the cavity 283 may be a portion of a circle from a cross-sectional view. The sidewall of the cavity 283 may have only one center of curvature.

In addition, the first encapsulant 28 includes a plurality of first fillers 284 adjacent to the sidewall of the cavity 283 and a plurality of second fillers 285 adjacent to the outer surface 281 of the first encapsulant 28. Since the cavity 283 may be formed around the truncated solder bump 43 (e.g., rather than by laser drilling), the first fillers 284 near or nearest the sidewall of the cavity 283 are completely or substantially intact and uncut. The first fillers 284 maintain their original smooth surfaces of substantially spherical shapes (or ellipsoidal shapes) and have no machining mark. Further, a surface roughness of the sidewall of the cavity 283 (e.g., of the entire sidewall of the cavity 283) is substantially consistent. In addition, the outer surface 281 of the first encapsulant 28 may be formed by machining such as grinding, cutting, or laser drilling, thus, some of the second fillers 285 are truncated and exposed on the outer surface 281 of the first encapsulant 28. Each of the truncated second fillers 285 has a substantially flat surface 2851, and the surfaces 2851 of the truncated second fillers 285 may be substantially coplanar with the outer surface 281 of the first encapsulant 28. In addition, a surface roughness of the sidewall of the cavity 283 is less than a surface roughness of the outer surface 281 of the first encapsulant 28 (e.g., by a factor of about 0.9 or less, or by a factor of about 0.8 or less, or by a factor of about 0.7 or less).

The cavity 283 of the first encapsulant 28 defines an opening 2831 on the outer surface 281 of the first encapsulant 28. The opening 2831 has a maximum width W₁ which is equal to a maximum width of the surface 431 of the truncated solder bump 43. Further, the first outer through hole 181 has a maximum width W₂, and the first outer pad 15 has a maximum width W₃. A ratio of the maximum width W₁ of the opening 2831 of the cavity 283 to the maximum width W₂ of the first outer through hole 181 is equal to or greater than about 1.08, such as greater than about 1.10, about 1.16, about 1.18, about 1.19, about 1.21, about 1.26, about 1.28, about 1.29, or about 1.30. The maximum width W₁ of the opening 2831 of the cavity 283 may be greater than the maximum width W₃ of the first outer pad 15 (e.g., by a factor of about 1.1 or more, by a factor of about 1.2 or more, or by a factor of about 1.3 or more).

A second height h₂ is measured from a bottom surface of the first outer pad 15 to the outer surface 281 of the first encapsulant 28 along a vertical direction of the substrate 1 in the orientation shown in FIG. 13. Thus, the truncated solder bump 43 has the second height h₂. The second height h₂ of the truncated solder bump 43 is substantially equal to the height H₁ of FIG. 2. The second height h₂ of the truncated solder bump 43 is less than the first height h₁ of the solder bump 42 of FIG. 9 and FIG. 10 by a factor of about 0.4 or less, about 0.33 or less, or about 0.3 or less. For example, more than one half of the solder bump 42 of FIG. 9 and FIG. 10 is removed. The removed portion of the first encapsulant 28 exceeds the plane including point E and point F of FIG. 10. The plane including point E and point F of FIG. 10 is removed. Thus, the maximum width W₁ of the opening 2831 of the cavity 283 is correspondingly less than the maximum width W₅ of the solder bump 42 of FIG. 10.

Referring to FIG. 14, at least one flux 44 is applied to the corresponding truncated solder bump 43 by, for example, printing with a stencil having openings. It is noted that the flux 44 is not a complement material (such as a solder bump, a pre-solder or paste). A material of the flux 44 is different from a material of the truncated solder bump 43. Then, a heating process is conducted to reflow the truncated solder bump 43 to form a connecting element 30 so as to obtain the semiconductor package structure 4 of FIG. 1. It is noted that the flux 44 may be used to increase a cohesion force of the melted truncated solder bump 43 and may be vaporized away (e.g., substantially completely vaporized away) during a reflow process. Thus, the flux 44 may not increase the volume of the connecting element 30. As shown in FIG. 1, the connecting element 30 is disposed adjacent to the first surface 11 of the substrate 1, and is disposed in the cavity 283. In the embodiment of FIG. 1, the semiconductor package structure 4 includes a plurality of connecting elements 30 that are disposed over respective ones of the first outer pads 15 positioned around the first semiconductor die 24. The connecting element 30 is formed by reflowing the truncated solder bump 43 (e.g., rather than by fusing two stacked solder bumps or by fusing a solder bump and a complement solder paste). Thus, the periphery surface of the connecting element 30 may be a curved surface due to cohesion forces. In some embodiments, a portion of the connecting element 30 is substantially in a spherical shape, and the peripheral surface of the connecting element 30 has only one center of curvature. In some embodiments, the connecting element 30 may have a shape that is a portion of a substantially spherical shape, and may not include any neck portion. The connecting element 30 is disposed adjacent to the first surface 101 of the substrate body 10, and may not be encapsulated or covered by the first encapsulant 28. In the embodiment of FIG. 1, a volume of the connecting element 30 is substantially equal to the volume capacity of the accommodating space 34. In addition, the second portion 302 of the connecting element 30 is a free end (not bonded or connected to another device or component) in the semiconductor package structure 4. In further manufacturing or assembly processes, the free end may be bonded or connected to another device or component.

The gap 33 is defined between a periphery surface of the first portion 301 (see FIG. 2) of the connecting element 30 and a sidewall of a portion of the cavity 283. The gap 33 extends to the first surface 11 of the substrate 1, and the connecting element 30 may not contact the first encapsulant 18 from a cross-sectional view. A maximum lateral width of the cavity 283 (e.g., a maximum width of an opening 2831) is greater than a maximum lateral width of the connecting element 30 (e.g., by a factor of about 1.1 or more, by a factor of about 1.2 or more, or by a factor of about 1.3 or more), thus, there is empty space (the gap 33) between the periphery surface of the first portion 301 of the connecting element 30 and the sidewall of the portion of the cavity 283, and the connecting element 30 does not fully fill the cavity 283. In addition, the second portion 302 of the connecting element 30 extends beyond/protrudes from an outer surface 281 of the first encapsulant 28, where the outer surface 281 of the first encapsulant 28 is a bottom surface of the first encapsulant 28 on the side of the semiconductor package structure 4 including the first encapsulant 28, and is substantially parallel with the first surface 11 of the substrate 1.

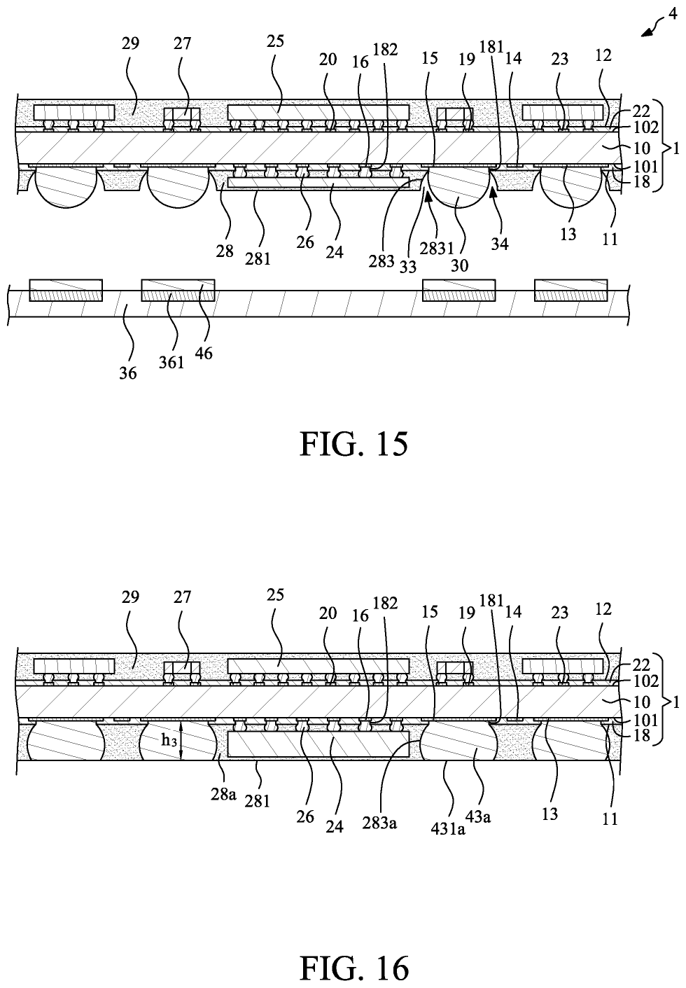

FIG. 15 illustrates a method for manufacturing a semiconductor package structure according to embodiments of the present disclosure. In some embodiments, the method is for manufacturing the semiconductor package structure 5 shown in FIG. 6. In some embodiments, the semiconductor package structure 4 illustrated in FIG. 1 and FIG. 2 is bonded to a device 36 (e.g., a motherboard or a semiconductor package). As shown in FIG. 15, the second portion 302 of the connecting element 30 is bonded to a pre-solder 46 on an electrical contact 361 (e.g., a bonding pad) of the device 36, so as to obtain the semiconductor package structure 5 illustrated in FIG. 6.

FIG. 16 illustrates a method for manufacturing a semiconductor package structure according to some embodiments of the present disclosure. In some embodiments, the method is for manufacturing the semiconductor package structure 4a shown in FIG. 4 and FIG. 5. The initial stages of the illustrated process are the same as, or similar to, the stages illustrated in FIG. 8 to FIG. 11. FIG. 16 depicts a stage subsequent to that depicted in FIG. 11.

Referring to FIG. 16, a portion of the first encapsulant 28 and the solder bump 42 are removed (e.g., concurrently) by, for example, grinding. Thus, the first encapsulant 28 and the solder bump 42 are thinned (e.g., concurrently) so that the first encapsulant 28a has an outer surface 281, and the solder bump 42 is truncated to become a truncated solder bump 43a having a substantially flat surface 431a. The surface 431a of the truncated solder bump 43a may be substantially coplanar with the outer surface 281 of the first encapsulant 28a. The truncated solder bump 43 is disposed in a cavity 283a defined by the first encapsulant 28a. A third height h₃ is measured from a bottom surface of the first outer pad 15 to the outer surface 281 of the first encapsulant 28a along a vertical direction of the substrate 1 in the orientation shown in FIG. 16. Thus, the truncated solder bump 43a has the third height h₃. The third height h₃ of the truncated solder bump 43a is substantially equal to the height H₂ of FIG. 5. The third height h₃ of the truncated solder bump 43a is greater than the second height h₂ of the truncated solder bump 43 of FIG. 12. Another stage of the manufacturing process shown in FIG. 16 is similar to the stage illustrated in FIG. 14, so as to obtain the semiconductor package structure 4a shown in FIG. 4 and FIG. 5.

In one or more embodiments, the second portion 302 of the connecting element 30a of the semiconductor package structure 4a illustrated in FIG. 4 and FIG. 5 is bonded to a pre-solder 46 (see FIG. 15) on an electrical contact 361 (e.g., a bonding pad) of a device 36 (e.g., a motherboard or a semiconductor package), so as to obtain the semiconductor package structure 5a illustrated in FIG. 7.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a characteristic or quantity can be deemed to be “substantially” consistent if a maximum numerical value of the characteristic or quantity is within a range of variation of less than or equal to +10% of a minimum numerical value of the characteristic or quantity, such as less than or equal to +5%, less than or equal to +4%, less than or equal to +3%, less than or equal to +2%, less than or equal to +1%, less than or equal to +0.5%, less than or equal to +0.1%, or less than or equal to +0.05%.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A semiconductor package structure, comprising:
a substrate having a first surface and a second surface opposite to the first surface;
an encapsulant disposed on the first surface of the substrate, and defining a cavity having a sidewall, wherein an accommodating space is defined by the sidewall of the cavity of the encapsulant and the substrate, and the accommodating space has a volume capacity; and
a connecting element disposed adjacent to the first surface of the substrate and in the cavity, wherein a volume of the connecting element is substantially equal to the volume capacity of the accommodating space.

2. The semiconductor package structure of claim 1, wherein:
a portion of the connecting element has a periphery surface, and a gap is defined between the periphery surface of the portion of the connecting element and the sidewall of the cavity, and
the encapsulant has an outer surface, and the connecting element extends beyond the outer surface of the encapsulant.

3. The semiconductor package structure of claim 2, wherein the gap extends to the first surface of the substrate.

4. The semiconductor package structure of claim 1, wherein the encapsulant has an outer surface, and the sidewall of the cavity extends from the outer surface of the encapsulant to the first surface of the substrate.

5. The semiconductor package structure of claim 1, wherein a curvature of the sidewall of the cavity is continuous.

6. The semiconductor package structure of claim 1, wherein the sidewall of the cavity defines a portion of an object having a substantially spherical shape.

7. The semiconductor package structure of claim 1, wherein the connecting element has a shape that is a portion of a substantially spherical shape.

8. The semiconductor package structure of claim 1, wherein the substrate includes a first circuit layer, the substrate defines at least one first outer through hole corresponding to the cavity of the encapsulant and exposing a portion of the first circuit layer, the encapsulant has an outer surface, the cavity of the encapsulant defines an opening on the outer surface of the encapsulant, and a ratio of a maximum width W₁ of the opening of the cavity to a maximum width W₂ of the first outer through hole is equal to or greater than 1.08.

9. The semiconductor package structure of claim 1, wherein the encapsulant includes a plurality of first fillers adjacent to a sidewall of the cavity, and at least some of the first fillers adjacent to the sidewall of the cavity are intact.

10. The semiconductor package structure of claim 9, wherein the encapsulant has an outer surface and includes a plurality of second fillers adjacent to the outer surface of the encapsulant, and at least some of the second fillers are truncated and exposed at the outer surface of the encapsulant.

11. The semiconductor package structure of claim 1, wherein a surface roughness of the sidewall of the cavity is substantially consistent.

12. The semiconductor package structure of claim 1, wherein the encapsulant has an outer surface, and a surface roughness of the sidewall of the cavity is less than a surface roughness of the outer surface of the encapsulant.

13. The semiconductor package structure of claim 1, wherein the connecting element does not contact the encapsulant from a cross-sectional view.

14. A method for manufacturing a semiconductor package structure, comprising:
(a) providing a substrate and a first semiconductor die, wherein the substrate has a first surface and a second surface, and the first semiconductor die is electrically connected to the first surface of the substrate;
(b) forming at least one solder bump adjacent to the first surface of the substrate;
(c) forming a first encapsulant to encapsulate the first semiconductor die and the solder bump;
(d) thinning the first encapsulant and the solder bump to truncate the solder bump and form an outer surface of the first encapsulant, wherein the truncated solder bump is disposed in a cavity defined by the first encapsulant, and a sidewall of the cavity extends from the outer surface of the first encapsulant to the first surface of the substrate; and
(e) reflowing the truncated solder bump to form a connecting element, wherein a gap is defined between a periphery surface of the connecting element and a sidewall of the cavity, and the connecting element extends beyond the outer surface of the first encapsulant.

15. The method according to claim 14, wherein (a) further comprises providing a second semiconductor die electrically connected to the second surface of the substrate; and wherein (c) further comprises forming a second encapsulant to encapsulate the second semiconductor die.

16. The method according to claim 14, wherein the substrate includes a circuit layer that includes a pad, and in (b), the solder bump is disposed on the pad, and a maximum width of the solder bump is greater than a maximum width of the pad.

17. The method according to claim 14, wherein in (e), the gap extends to the first surface of the substrate.

18. The method according to claim 14, wherein in (e), the sidewall of the cavity defines a portion of an object having a substantially spherical shape, and the connecting element has a shape that is a portion of a substantially spherical shape.

19. The method according to claim 14, wherein in (e), a surface roughness of the sidewall of the cavity is less than a surface roughness of the outer surface of the first encapsulant.

20. The method according to claim 14, further comprising bonding the connecting element to a device.
